(19) United States
(12) Patent Application Publication
(10) Pub. No.: US 2024/0258079 A1
(43) Pub. Date: Aug. 1, 2024

(54) CAPACITIVELY COUPLED PLASMA SUBSTRATE PROCESSING APPARATUS

(71) Applicant: INNOVATION FOR CREATIVE DEVICES CO., LTD., Anseong-si (KR)

(72) Inventors: Buil JEON, Anseong-si (KR); Taeho SHIN, Yongin-si (KR); Dooho LIM, Suwon-si (KR); Jungsu PARK, Pyeongtaek-si (KR); Bumsoo ON, Yongin-si (KR); Seungho LEE, Yongin-si (KR)

(21) Appl. No.: 18/631,194

(22) Filed: Apr. 10, 2024

Related U.S. Application Data
(63) Continuation of application No. PCT/KR2022/015714, filed on Oct. 17, 2022.

(30) Foreign Application Priority Data
Oct. 20, 2021 (KR) 10-2021-0140021

(51) Int. Cl. H01J 37/32

(52) U.S. Cl. CPC H01J 37/32568; H01J 37/32091; H01J 37/3211; H01J 37/32146; H01J 37/32357; H01J 2237/334

(57) ABSTRACT

A plasma substrate processing apparatus according to one embodiment of the present invention comprises: a process chamber; an upper electrode disposed in the process chamber; a substrate holder disposed under the upper electrode and facing the upper electrode to support a substrate; and an RF power source for applying RF power to the substrate holder. The upper electrode includes: an upper electrode conductive plate having lower surfaces with different heights from the substrate holder according to positions thereof; and a compensating plate coupled to a lower portion of the conductive plate, having a different thickness according to positions thereof to compensate for a height difference according to the positions of the upper electrode conductive plate, and having a dielectric constant. The lower surface of the compensating plate is coplanar.

### CROSS-REFERENCE TO RELATED APPLICATIONS

This application is a continuation of and claims priority to PCT/KR2022/015714 filed on Oct. 17, 2022, which claims priority to Korea Patent Application No. 10-2021-0140021 filed on Oct. 20, 2021, the entireties of which are both hereby incorporated by reference.

### TECHNICAL FIELD

The present disclosure relates to a plasma apparatus, and relates to a capacitively-coupled plasma apparatus having improved plasma spatial uniformity, and more particularly, to a plasma substrate apparatus for treating a substrate by generating capacitively-coupled plasma using a compensate plate for compensating for a non-uniform electric field.

### BACKGROUND ART

Plasma treatment devices are used for etching, cleaning, surface treatment, or the like. For example, plasma etching treatment devices require independent control of active species density, plasma density, and ion energy to obtain high etching selectivity and etching rate. A low-frequency RF power source below a band of several MHz is mainly used to control ion energy, and a high-frequency RF power source above a band of tens of MHz is mainly used to control plasma density and active species density. In addition, power of the low-frequency RF power source is increased to increase ion energy. Increasing the power of the high-frequency RF power source is required to increase plasma density. However, increasing the power of the high-frequency RF power source may cause the active species to be over-decomposed, which may reduce etching selectivity. An electrostatic chuck is easily damaged by a high voltage.

Pulse plasma may change plasma characteristics by turning RF power on and off to reduce electron temperature and plasma density in a power-off interval. Accordingly, pulse plasma may reduce notching and bowing.

An RF frequency of capacitively-coupled plasma is increased to obtain high plasma density and high etching rate. With the increase in RF frequency, standing wave effect, edge effect, or harmonic effect reduce plasma uniformity or process uniformity. A step was provided on an electrode, applied with RF power, to spatially change the strength of an electric field. However, such a step may disturb a flow of fluid and cause contamination occurring foreign objects caused by the step. A plasma density distribution depends on gas, pressure, and RF power. The plasma density distribution changes when process conditions change. However, a power electrode having a step or curvature makes it difficult to independently control the plasma density distribution under various process conditions. Accordingly, there is requirement for a new structure that may achieve a uniform plasma density even when the plasma density distribution changes due to changes in process conditions.

A conventional plasma device having a dual chamber structure includes an upper chamber and a lower chamber separated by a diffusion plate. Each of the upper and lower chambers generates plasma, and the diffusion plate separates each plasma region and is used as a path for movement of active species. Due to non-uniformity of the plasma in the upper chamber, the diffusion plate makes it difficult to control spatially uniform active species in the lower chamber. A structure of the diffusion plate for preventing mutual plasma diffusion makes it difficult to control pressure independently. Accordingly, the upper and lower chambers have limitations in securing desired plasma characteristics. The diffusion plate has a through-hole having a sufficiently small diameter to prevent mutual leakage of the upper and lower plasmas. Thus, conductance of the diffusion plate is reduced, the active species are deposited on the diffusion plate as foreign objects, and the deposited foreign objects may be separated to release contaminated particles. In addition, the plasma in the lower chamber interferes with the plasma in the upper chamber, and the plasma in the lower chamber has difficulty in providing plasma spatial uniformity due to non-uniformity of active species, or the like.

### DISCLOSURE OF THE INVENTION

### Technical Problem

The present disclosure provides a substrate treatment apparatus for providing a uniform capacitively-coupled plasma process using a compensating plate.

### Technical Solution

A plasma substrate processing apparatus according to an embodiment includes: a process chamber; an upper electrode disposed in the process chamber; a substrate holder disposed below the upper electrode and disposed to oppose the upper electrode to support the substrate; and an RF power source applying RF power to the substrate holder. The upper electrode may include: an upper electrode conductive plate having a lower surface having different heights from the substrate holder depending on location; and a compensation plate coupled to a lower portion of the upper electrode conductive plate to have different thicknesses depending on location to compensate for a height difference depending on location and having a dielectric constant. A lower surface of the compensation plate may be a coplanar surface.

In an embodiment, the upper electrode may include a plurality of through-holes penetrating through the upper electrode conductive plate and the compensation plate.

In an embodiment, the upper electrode may be electrically grounded.

In an embodiment, the compensation plate may be an insulator or semiconductor having a dielectric constant, the upper electrode may have a constant thickness, the upper electrode conductive layer may have a thickness varying depending on location, and the compensation plate may have a thickness varying depending on location such that the thickness of the upper electrode is maintained to be constant.

In an embodiment, the compensation plate may include at least one of silicon, silicon oxide, silicon nitride, and silicon oxynitride.

In an embodiment, the thickness of the compensation plate may be greatest in at least one of a central region and an edge region, the central region may have a circular shape, and the edge region may have a ring shape.

In an embodiment, the plasma substrate processing apparatus may further include: at least one ground ring. The ground ring may be disposed below the upper electrode to surround plasma between the substrate holder and the upper electrode and has a ring shape, and an inner diameter of the ground ring may be larger than an outer diameter of the substrate holder.

In an embodiment, the plasma substrate processing apparatus may further include: at least one ground cavity. The ground cavity may be disposed below the upper electrode to surround plasma between the substrate holder and the upper electrode and have a cylindrical shape, the ground cavity may include a plurality of slits, and an inner diameter of the ground cavity may be larger than an outer diameter of the substrate holder.

In an embodiment, the plasma substrate processing apparatus may further include: a remote plasma generator generating remote plasma and active species; an auxiliary chamber having an opening connected to an output port of the remote plasma generator and receiving and diffusing the active species of the remote plasma generator to be provided to the process chamber; a first baffle disposed at the opening of the auxiliary chamber; and a second baffle partitioning the auxiliary chamber and the process chamber and transmitting the active species. The second baffle may be disposed to be spaced apart from the upper electrode. The second baffle may be electrically grounded, may oppose the auxiliary chamber, and may include a plurality of first through-holes. The upper electrode may be electrically grounded, may be spaced apart from the second baffle, and may include a plurality of second through-holes.

In an embodiment, the second through-holes may be disposed to avoid overlapping the first through-holes.

In an embodiment, a diameter of the second through-hole may be more than twice a thickness of the plasma sheath between the upper electrode and plasma, and the plasma may permeate into the second through-holes.

In an embodiment, a gap between the second baffle and the upper electrode may be less than several millimeters, and a gap between the substrate holder and the lower surface of the upper electrode may be larger than the gap between the second baffle and the upper substrate.

In an embodiment, a diameter of the first through-hole of the second baffle may be smaller than a diameter of the second through-hole of the upper electrode.

In an embodiment, the second through-holes may be disposed to avoid overlapping the first through-holes.

In an embodiment, the first baffle may include: a disk having an inclined outer surface; and a ring plate having an inclined inner surface and an inclined outer surface and disposed to surround the disk with a predetermined gap from the disk. The outer surface of the disk may have an outer diameter increasing with height, and the inner surface of the ring plate may have an inner diameter increasing with height.

In an embodiment, the disk and the ring plate may be fixed by a plurality of bridges, and the ring plate may be fixed to the auxiliary chamber by a plurality of columns.

In an embodiment, the first baffle may include a plurality of through-holes, through-holes disposed at a center of the first baffle may be inclined holes directed to a central axis, and the through-holes disposed at an edge of the first baffle may be inclined holes directed to the outside.

In an embodiment, the RF power source may include a low-frequency power source and a high-frequency power source. The plasma substrate processing apparatus may further include a pulse controller controlling the low-frequency RF power source and the high-frequency RF power source. Each of the low-frequency RF power source and the high-frequency RF power source may operate in pulse mode.

In an embodiment, the remote plasma generator may be an inductively-coupled plasma source including an induction coil wound around a dielectric cylinder.

In an embodiment, a diameter of the output port of the remote plasma generator may be 50 millimeters to 150 millimeters, the auxiliary chamber may have a truncated cone shape, and the opening of the auxiliary chamber may be disposed in a truncated portion.

In an embodiment, the plasma substrate processing apparatus may further include: an auxiliary chamber connected to the process chamber; a power electrode receiving RF power from an auxiliary RF power source to generate capacitively-coupled plasma and active species in the auxiliary chamber; and an auxiliary ground electrode partitioning the auxiliary chamber and the process chamber and transmitting the active species. The auxiliary ground electrode may be disposed to be spaced apart from the upper electrode. The auxiliary ground electrode may be electrically grounded, may oppose the auxiliary chamber, and may include a plurality of first through-holes. The upper electrode may be electrically grounded, may be spaced apart from the auxiliary ground electrode, and may include a plurality of second through-holes.

In an embodiment, the auxiliary ground electrode may include: an auxiliary electrode conductive plate having an upper surface having a height varying on location; and a compensation plate coupled to an upper portion of the auxiliary electrode conductive plate to have a thickness varying depending on location to compensate for a height difference depending on location and have a dielectric constant. The upper surface of the compensation plate may be a coplanar surface.

A plasma substrate processing apparatus according to an embodiment includes: a process chamber; an upper electrode disposed in the process chamber; a substrate holder disposed below the upper electrode and disposed to oppose the upper electrode to support the substrate; and an RF power source applying RF power to the substrate holder. The upper electrode may include: an upper electrode conductive plate; and a compensation plate coupled to a lower portion of the conductive plate and having a dielectric constant varying depending on location. A lower surface of the compensation plate may be a coplanar surface, and the compensation plate may be coupled to the upper electrode conductive plate.

In an embodiment, the compensation plate may be an insulator or semiconductor having a dielectric constant, the upper electrode conductive plate may have a constant thickness, and the compensation plate may be divided into a plurality of components to have a different dielectric constant varying depending location.

In an embodiment, the upper electrode may be grounded.

A plasma substrate processing apparatus according to an embodiment includes: a process chamber; an upper electrode disposed in the process chamber; a substrate holder disposed below the upper electrode and disposed to oppose the upper electrode to support the substrate; an RF power source applying RF power to the substrate holder; and at least one ground cavity. The ground cavity may be disposed below the upper electrode to surround plasma between the substrate holder and the upper electrode and has a cylindrical shape, the ground cavity may include a plurality of slits, and an inner diameter of the ground cavity may be larger than an outer diameter of the substrate holder.

### Advantageous Effects

As set forth above, a plasma substrate treatment apparatus according to an example embodiment may control plasma characteristics depending on location to suppress a standing wave effect and provide a uniform plasma process.

### BRIEF DESCRIPTION OF THE DRAWINGS

FIG. 1 is a conceptual diagram illustrating a plasma substrate processing apparatus according to an embodiment of the present disclosure.

FIG. 2 is a cross-sectional view illustrating an upper electrode of the substrate treatment apparatus of FIG. 1.

FIG. 3 is a conceptual diagram illustrating plasma density formed by the upper electrode of FIG. 2.

FIG. 4 is a diagram illustrating a signal of RF power applied to a substrate holder of FIG. 1.

FIG. 5 is a conceptual diagram illustrating a substrate treatment apparatus according to another embodiment of the present disclosure.

FIGS. 6A and 6B are a conceptual diagram and a perspective view illustrating a substrate treatment apparatus according to another embodiment of the present disclosure.

FIG. 7 is a conceptual diagram illustrating a substrate treatment apparatus according to another embodiment of the present disclosure.

FIG. 8A is a perspective view illustrating a first baffle in the plasma substrate processing apparatus of FIG. 7.

FIG. 8B is a cross-sectional view of the first baffle of FIG. 8A.

FIG. 9 is a conceptual diagram illustrating a second baffle and an upper electrode in the plasma substrate processing apparatus of FIG. 8.

FIG. 10 is a conceptual diagram illustrating a second baffle and an upper electrode in the plasma substrate processing apparatus of FIG. 8.

FIG. 11 is a plan view illustrating a second baffle according to an embodiment of the present disclosure.

FIG. 12 is a cross-sectional view illustrating a first baffle according to another embodiment of the present disclosure.

FIG. 13 is a cross-sectional view illustrating a first baffle according to another embodiment of the present disclosure.

FIG. 14 is a perspective view illustrating an upper electrode and a second baffle according to an embodiment of the present disclosure.

FIG. 15 is a cross-sectional view of the upper electrode and the second baffle of FIG. 14.

FIG. 16 is a conceptual diagram illustrating a substrate treatment apparatus according to another embodiment of the present disclosure.

FIG. 17 is a conceptual diagram illustrating an upper electrode and an auxiliary electrode of the substrate treatment apparatus of FIG. 16.

FIG. 18 is a conceptual diagram illustrating a substrate treatment apparatus according to another embodiment of the present disclosure.

### MODE FOR CARRYING OUT THE INVENTION

A substrate treatment apparatus according to an embodiment of the present disclosure may include an upper electrode disposed to be spaced apart from a substrate holder. When high-frequency RF power is applied to the substrate holder to generate capacitively-coupled plasma, a spatially non-uniform plasma density distribution is formed due to standing wave effect, edge effect, or harmonic effect. For example, the spatial distribution in a plasma radial direction may have a central peak and/or an edge peak. However, the plasma density increases as the frequency of the RF power increases, so that high-frequency RF power of 60 MHz or higher may be used. However, such high-frequency RF power of 60 MHz or higher generates a spatially non-uniform plasma density distribution due to standing wave effect or harmonic effect.

According to an embodiment of the present disclosure, the central peak and/or the edge peak may be controlled even when a high-frequency RF power of 60 MHz or higher is used. Spatial control of the strength of an electric field may be performed by adjusting a gap distribution between the upper electrode and the lower electrode (substrate holder). When a step is provided on a lower surface of the grounded upper electrode to adjust a gap between the grounded upper electrode and the lower electrode (substrate holder), the step on the lower surface of the grounded upper electrode may affect conductance of gas. In addition, the step on the lower surface of the upper electrode may act as an obstacle to a flow of the gas in a discharge space. In addition, contaminants may be attached to a step portion on the lower surface of the upper electrode.

According to an example embodiment of the present disclosure, the upper electrode may spatially maintain the same thickness to eliminate the effect on the conductance when the active species move through the lower baffle. For example, the upper electrode may have a multilayer structure including an upper electrode conductive plate and a compensation plate therebelow. The upper electrode conductive plate has a lower surface having different heights depending on location, and the compensation plate is bonded to the lower surface of the conductive plate and has a different thickness depending on location to compensate for the height difference depending on the position and has a dielectric constant. A lower surface of the compensation plate may be a coplanar surface. The closer the dielectric constant of the compensation plate is to a vacuum electric constant, the more it may be advantageous. The compensation plate may be formed of silicon, silicon oxide, silicon nitride, silicon oxynitride, or aluminum oxide. A thickness of the compensation plate may vary depending on location. As the thickness of the compensation plate increases, the strength of the electric field in the discharge space at a corresponding location may decrease. Accordingly, the spatial distribution of the thickness of the compensation layer may control the central peak and/or the edge peak. The compensation layer may be decomposed and combined with the conductive perforated plate of the lower baffle. The compensation layer may be replaced with a new component as a consumable.

According to an embodiment of the present disclosure, at least one ground ring or ground cavity may be disposed to surround the discharge region to significantly reduce an effect on the conductance of the gas, suppress the standing wave effect, increase a resonant frequency of the cavity, and increase a ground area.

According to an embodiment of the present disclosure, ring-shaped ground rings may be disposed to surround the discharge space between the upper electrode and the substrate holder. The ground rings are grounded to increase a ground area of the plasma. In addition, the ground rings may be used to confine the plasma to the discharge space. The guard rings may be stacked vertically and grounded. Process byproducts may diffuse to a space between the ground rings to be discharged through a vacuum pump.

According to an example embodiment of the present disclosure, with the help of a remote plasma generator, high-frequency RF power of 60 MHz or higher may not be used to increase the plasma density.

A plasma substrate processing apparatus according to an embodiment of the present disclosure may independently generate plasma and active species using a remote plasma generator spatially separated from the auxiliary chamber and supply only active species to the auxiliary chamber. The remote plasma generator may independently generate active species and plasma and does not interfere with an RF power source of the process chamber.

The active species supplied to the auxiliary chamber are injected and diffused into a large area by a first baffle, and the auxiliary chamber provides sufficient space required for diffusion. A second baffle, disposed between the auxiliary chamber and the process chamber, has an optimized structure allowing active species in the auxiliary chamber to pass through the process chamber while blocking charged particles such as ions and electrons generated in the process chamber. The second baffle may move the active species to the lower chamber without loss, and may diffuse the moved active species in a shortest distance and uniformly inject the diffused active species into the process chamber.

The plasma treatment apparatus according to an embodiment of the present disclosure may independently generate active species using a remote plasma generator and supply the active species to a chamber including an auxiliary chamber and a process chamber. The remote plasma generator eliminates electrical interference with the process chamber and independently generates active species under optimal plasma conditions. A first baffle removes the plasma supplied by the remote plasma generator and supplies only active species to the auxiliary chamber. The first baffle injects and diffuses the active species over a large area. The auxiliary chamber and the process chamber are separated by a second baffle. The active species of the auxiliary chamber are supplied to the process chamber by passing through the grounded second baffle and/or the upper electrode. The substrate holder is disposed in the process chamber, and RF power applied to the substrate holder generates capacitively-coupled plasma between the substrate on the substrate holder and the upper electrode. As the active species are independently supplied to the process chamber, power of a high-frequency RF power source for generating active species in the process chamber may be reduced. In addition, power of a low-frequency RF power source for controlling the ion energy may be reduced to be mainly used for controlling the ion energy.

In the plasma substrate processing apparatus according to an embodiment of the present disclosure, the first baffle may distribute the active species spatially uniformly, and the upper electrode may be used as a ground electrode for the capacitively-coupled plasma generated in the lower chamber. The second baffle and the upper electrode may have a multilayer structure. The upper electrode has a sufficient diameter to allow plasma to permeate from a lower side, and the plasma permeating through an opening of the upper electrode may be blocked by the second baffle. Both the second baffle and the upper electrode are grounded, so that an area of a ground surface contacting the plasma may be increased and a bias voltage applied to a plasma sheath on a substrate side may be increased. Accordingly, power of the low-frequency RF power source for controlling the ion energy incident on the substrate may be reduced.

When charged particles (ions or electrons) collide with a wall, the charged particles may be neutralized. Accordingly, a method of blocking the ions or electrons is to prevent the presence of through-holes and allow the ions or electrons collide by permeating through the second baffle. On the other hand, neutral species or active species do not lose much of reactivity thereof in collisions. The charged particles may be neutralized due to collisions while moving from a lower portion to an upper portion, and the neutral species may move from an upper portion to a lower portion with minimal collisions. To this end, the second baffle may have a multilayer structure to have large vacuum conductance, and the openings of the second baffle and the upper electrode may be designed to avoid overlapping each other.

Each of the second baffle and the upper electrode may have a variety of through-hole structures of different shapes, such as a maximum-sized triangle, rectangle, or circle. When a plurality of perforated plates overlap each other to prevent the movement of charged particles, the perforated plates may not penetrate from top to bottom. In other words, particles cannot move from the bottom to the top without collision. A structure, which cannot move straightly from the bottom to the top without collision, may be designed to have maximum vacuum conductance. For example, when two perforated plates are used, a size of an opening formed in each of the perforated plates may be significantly increased such that each of the perforated plates has maximum conductance. When the two perforated plates overlap each other, there is no overlapping opening (penetrating portion).

In addition, a diameter of a hole of the lower baffle may be large enough to allow the plasma, generated in the lower chamber, to permeate through the lower baffle. For example, the diameter of the hole of the lower baffle may be several millimeters. The diameter of the hole of the lower baffle may be, in detail, 5 to 10 millimeters. The diameter of the hole in the lower baffle may be larger than a diameter of a hole of the upper baffle. Accordingly, plasma incident on the lower baffle may be blocked and neutralized by the upper baffle. In addition, a contact area with the plasma may be increased.

According to an example embodiment of the present disclosure, the second baffle and the upper electrode may be disposed to be spaced apart from each other, and the upper electrode may oppose a substrate applied with power of the RF power source. Accordingly, a ratio of a surface area of the upper electrode contacting the plasma to an area of the substrate may depend on a voltage applied to the substrate. Accordingly, increasing the surface area of the upper electrode contacting the plasma may increase a DC bias voltage applied to the substrate. As a result, higher ion energy may be obtained at the same RF power.

According to an example embodiment of the present disclosure, the high-frequency RF power and the low-frequency RF power applied to the substrate holder may be synchronized with each other to operate in pulse mode. The high-frequency RF power may include a high-power interval and a low-power interval, and the low-frequency RF power may have an ON interval in the low-power interval of the high-frequency RF power.

The substrate processing apparatus may filter charged particles in etching, deposition, cleaning, and other devices in the semiconductor process, and may allow only reactive species having reactivity to be used in a process apparatus.

The plasma substrate processing apparatus according to an example embodiment of the present disclosure may be applied to an atomic layer etching apparatus for semiconductor etching, a plasma cleaning apparatus, a deposition apparatus using plasma, or the like.

The first baffle may significantly reduce the loss caused by collision while the active species diffuses downwardly, and may uniformly diffuse the active species from an upper region having a diameter of about 10 cm to a lower region having a diameter of about 40 cm in a shortest distance.

Hereinafter, example embodiments will now be described more fully with reference to the accompanying drawings, in which some example embodiments are shown. Example embodiments may, however, be embodied in many different forms and should not be construed as being limited to the embodiments set forth herein. Rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements.

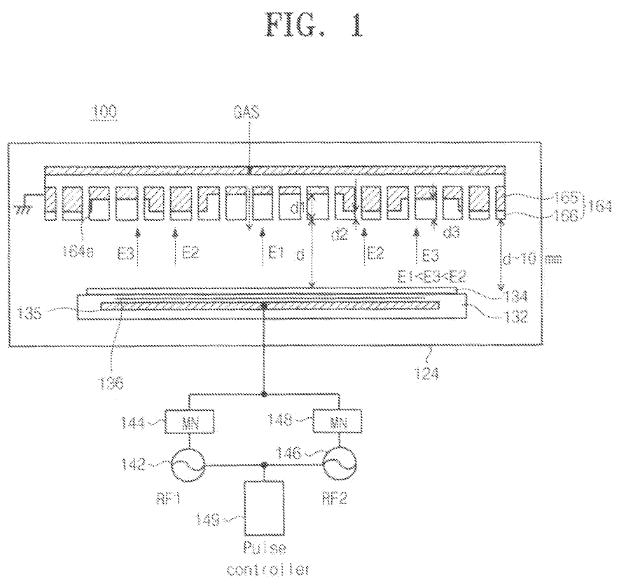

FIG. 1 is a conceptual diagram illustrating a plasma substrate processing apparatus according to an embodiment of the present disclosure.

FIG. 2 is a cross-sectional view illustrating an upper electrode of the substrate treatment apparatus of FIG. 1.

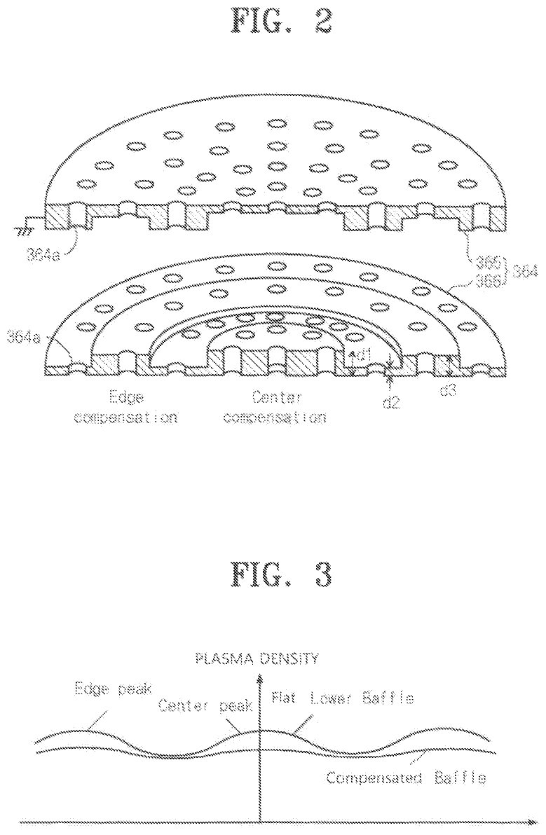

FIG. 3 is a conceptual diagram illustrating plasma density formed by the upper electrode of FIG. 2.

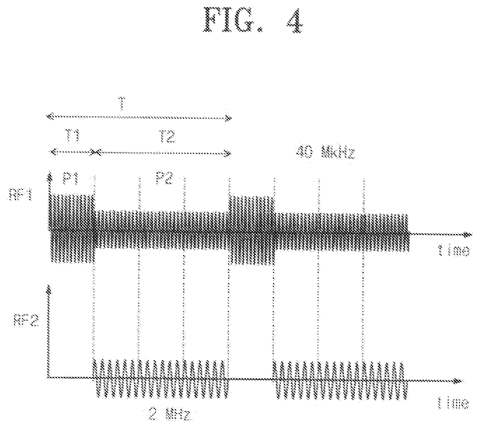

FIG. 4 is a diagram illustrating a signal of RF power applied to a substrate holder of FIG. 1

Referring to FIGS. 1 to 4, a plasma substrate processing apparatus 100 includes:

a process chamber 124; an upper electrode 164 disposed in the process chamber 124; a substrate holder 132 disposed below the upper electrode 164 and disposed to oppose the upper electrode 164 to support the substrate 134; and RF power sources 142 and 144 applying RF power to the substrate holder 134.

The upper electrode 164 may include: an upper electrode conductive plate 165 having a lower surface having different heights from the substrate holder 132 depending on location; and a compensation plate 166 coupled to a lower portion of the upper electrode conductive plate 165 to have different thicknesses depending on location to compensate for a height difference depending on location and having a dielectric constant. The lower surface of the compensation plate 166 is a coplanar surface.

The plasma substrate processing apparatus 100 may be an etching apparatus, a cleaning apparatus, a surface treatment apparatus, or a deposition apparatus. The substrate may be a semiconductor substrate, a glass substrate, or a plastic substrate.

The process chamber 124 may be formed of a conductive material and grounded, and may have a cylindrical shape.

The upper electrode 164 may act as a ground electrode and a gas distributor. The upper electrode may receive gas from the outside, have a gas buffer space therein, and inject gas through a plurality of through-holes 164a.

The through-holes 164a may be disposed to penetrate through the upper electrode conductive plate 165 and the compensation plate 166. The upper electrode 164 may have a predetermined thickness, and the thickness of the upper electrode conductive plate 165 may vary depending on location. The thickness of the compensation plate 166 may vary depending on location such that a thickness of the upper electrode 164 is maintained to be constant.

As frequencies of the RF power sources 142 and 146 increase, standing wave effect or harmonic effect may occur. The standing wave effect and the harmonic effect may increase as a frequency increases, and may form a center peak and/or an edge peak of plasma density.

As a frequency of an RF power source increases, plasma density may increase and an electron temperature may decrease, so that various process environments may be established compared to a low-frequency RF power source.

Conventionally, a surface step may be provided on the upper electrode supplied with RF power to spatially control the strength of an electric field in capacitively-coupled plasma. However, the surface step of the upper electrode may be a cause of contamination deposition and particle formation. Even when the upper electrode has a surface curvature, it may be difficult to manufacture an upper electrode having such a surface curvature, and the upper electrode having such a surface curvature may interfere with a flow of fluid to cause difficulty in providing a spatially uniform process.

The compensation plate 366 may include at least one of silicon, silicon oxide, silicon nitride, and silicon oxynitride. The compensation plate 366 may have a greatest thickness in at least one of the central region and/or the edge region. The central region may have a circular shape, and the edge region may have a ring shape.

According to an embodiment of the present disclosure, the upper electrode conductive plate 165 of the upper electrode 164 acting as a ground electrode in the capacitively-coupled plasma may have a curvature or step on a lower surface thereof. The compensation plate 366 may adjust a location-dependent strength of an electric field in a discharge space between the upper electrode 164 and the substrate holder 132 applied with the RF power while eliminating such a curvature or step.

The upper electrode 164 may have through-holes 164a, and conductances of the through-holes 164a may be different from each other when the thickness of the upper electrode varies depending on location. The upper electrode may have a multilayer structure and be planar with a constant thickness to suppress an effect on a flow of fluid in the discharge space while maintaining the conductances of the through-holes 164a constant to be constant.

Specifically, the upper electrode 164 may include an upper electrode conductive plate formed of a conductor and a compensation plate 166 that is disposed below the upper electrode conductive plate and is an insulator or semiconductor having a dielectric constant and. The compensation plate 166 may be an insulator or semiconductor having a dielectric constant. The through-holes 164a of the upper electrode may be disposed to penetrate through the upper electrode conductive plate and the compensation plate. Accordingly, a lower surface of the lower electrode may be a coplanar surface.

In the discharge region, electric field strengths E1, E, and E3 may be determined by thicknesses d1, d2, and d3, a dielectric constant ε of a compensation layer, and a height d of the discharge region. For example, as the dielectric constant of the compensation layer 166 decreases, a difference in electric field strength may increase. Accordingly, a material of the compensation layer 166 may be silicon oxide, silicon nitride, silicon oxynitride, aluminum oxide, or silicon.

An electric field E in a vacuum region may be given as follows:

$$\\ {ε}_{0} {a}_{1} ⊤ ε a$$

where ε is a dielectric constant of the compensation layer 166, d1 is a thickness of the compensation layer 166, and Vo is an applied voltage difference. ε₀ is a dielectric constant of vacuum. d is a height of the discharge region. Therefore, as the thickness d1 of the compensation layer 166 increases, the electric field strength decreases.

The thickness of the compensation layer 166 may be about ½ to 1/10 of the height d of the discharge region. For example, when the height d of the discharge region is 10 mm, a maximum thickness d1 of the compensation layer 166 may be 5 mm to 1 mm. The greater the thickness of the compensation layer 166, the lower the electric field strength in the corresponding discharge region. When d1>d3>d2, E1<E3<E2. E1 is an electric field of the discharge region corresponding to d1. Accordingly, the thickness of the compensation layer 166 may be selected depending on location to suppress the center peak and/or edge peak of the plasma density. The compensation layer 166 may provide reliability because the compensation layer 166 is not sputtered by low ion energy due to the grounded upper electrode.

In addition, an electric field strength distribution in the discharge region may depend on the dielectric constant ε of the compensation layer 166 and the height d of the discharge region. Accordingly, the electric field strength distribution in the discharge region may be changed when the height d of the discharge region is adjusted. As a result, decreasing the height d of the discharge region may reduce the electric field strength at the center to generate uniform plasma under process conditions in which a large center peak is exhibited.

According to a modified embodiment of the present disclosure, the thickness of the compensation layer 166 may abruptly change depending on location but may gradually change.

The substrate holder 132 may support the substrate 134 and receive the power of the RF power sources 142 and 146 to generate capacitively-coupled plasma. The substrate holder 132 may include an electrode 136 for an electrostatic chuck. The electrostatic chuck may receive a DC high voltage from the outside to fix the substrate 134 with electrostatic force. The substrate holder 132 may include a power electrode 135 receiving the power of the RF power source. An electrode 136 of the electrostatic chuck may be disposed on the power electrode 135.

The substrate 134 may be a semiconductor substrate, a glass substrate, or a plastic substrate. The semiconductor substrate may be a silicon wafer having a diameter of 300 mm.

The RF power sources 142 and 146 may supply RF power to the power electrode 135. The RF power sources 142 and 146 may include: a low-frequency RF power source 146 having a frequency of 13.56 MHz or lower; and a high-frequency RF power source 142 having a frequency of more than 13.56 MHz and less than 60 MHz. A frequency of the low-frequency RF power source 146 may be 400 kHz to 10 MHz. A frequency of the high-frequency RF power source 142 may be 20 MHz to 60 MHz. The RF power sources 142 and 146 may operate in pulse mode or continuous mode.

The low-frequency RF power source 146 may supply low-frequency RF power to the power electrode 135 through a first impedance matching network 148. The high-frequency RF power source 142 may supply low-frequency RF power to the power electrode 135 through a second impedance matching network 144.

A pulse controller 149 may control the low-frequency RF power source 146 and the high-frequency RF power source 142. Each of the low-frequency RF power and the high-frequency RF power may operate in pulse mode.

The high-frequency RF signal RF1 of the high-frequency RF power source 122 may repeat a high-power interval T1 and a low-power interval T2 at a constant period T. The high-power interval T1 may increase the plasma density in the discharge region. The low-power interval T2 may suppress the complete extinction of plasma, so that the high-frequency RF power source 122 may independently control stable plasma generation in the next high-power interval T1. A frequency of the high-frequency RF power source 122 may be 13.56 MHz to 60 MHz.

On the other hand, in the high-power interval T1, the low-frequency RF signal RF2 of the low-frequency RF power source 146 may be turned off. In the low-power interval T2, the low-frequency RF signal RF2 of the low-frequency RF power may be provided. The low-frequency RF signal RF2 may independently control energy of ions. Plasma properties may be independently controlled to be appropriate for each process.

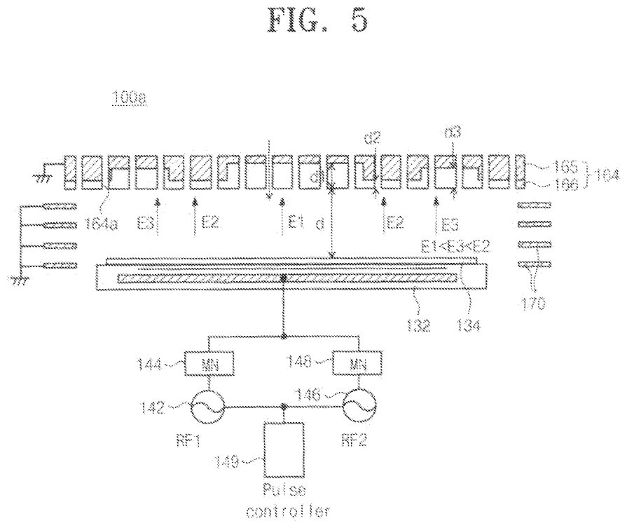

FIG. 5 is a conceptual diagram illustrating a substrate treatment apparatus according to another embodiment of the present disclosure.

Referring to FIG. 5, the plasma substrate processing apparatus 100a includes:

a process chamber 124; an upper electrode 164 disposed in the process chamber 124; a substrate holder 132 disposed below the upper electrode 164 and disposed to oppose the upper electrode 164 to support the substrate 134; and RF power sources 142 and 144 applying RF power to the substrate holder 134.

The upper electrode 164 may include: an upper electrode conductive plate 165 having a lower surface having different heights from the substrate holder 132 depending on location; and a compensation plate 166 coupled to a lower portion of the upper electrode conductive plate 165 to have different thicknesses depending on location to compensate for a height difference depending on location and having a dielectric constant. The lower surface of the compensation plate 166 is a coplanar surface.

In a cylindrical cavity structure surrounding a parallel plate capacitor, a resonant frequency of standing wave may be in inverse proportion to a radius of the lower chamber 124. Specifically, the resonant angular frequency ω may be given as follows:

$$\\ ω = 2.405 c / a ,$$

where 2.405 is a location of first zero of a Bessel function, c is the speed of light, and a is a radius of the cylindrical cavity.

Conventionally, when a cylindrical cavity in capacitively-coupled plasma is a process chamber and a radius of the process chamber is 0.3 m, a resonant frequency may be about 400 MHz. When a diameter of the process chamber 124 increases, a resonant frequency may decrease. When a driving frequency of the RF power source 142 is 100 MHz, fourth harmonics may match the resonant frequency to significantly cause a standing wave effect. Accordingly, it may be preferable that a driving frequency of the RF power source 142 and a resonant frequency of a resonator formed by the process chamber have a large difference. However, the driving frequency of the RF power source 142 should be maintained above several tens of MHz to increase the plasma density and decrease an electron temperature. Therefore, an increase in the resonant frequency is required.

A radius of the process chamber needs to be decreased to increase the resonant frequency of the resonator formed by the process chamber. Alternatively, the radius of the process chamber needs to be decrease to reduce the standing wave effect.

At least one ground ring 170 may be disposed to surround the discharge region to decrease the radius of the process chamber. When an inner radius of the ground ring is 0.2 m, the resonant frequency may be about 570 MHz. Accordingly, the resonant frequency of the resonator may increase, the standing wave effect may be relatively reduced, and a ground area contacting the plasma may be increased. Since the resonant frequency may be achieved by harmonics of the RF power source 142, the standing wave effect may be further reduced when the frequency of the RF power source 142 is used below 60 MHz. In addition, n-th harmonics of the driving frequency of the RF power source 142 may be selected to be different from the resonant frequency.

The ground ring 170 may be disposed below the upper electrode 164 to surround plasma between the substrate holder 132 and the upper electrode 160, and may have a ring shape. An inner diameter of the ground ring 170 is larger than an outer diameter of the substrate holder 132. The ground ring 170 may limit the discharge space to limit a space in which the plasma diffuses. In addition, the ground ring 170 may be grounded to increase the ground area and increase a DC bias voltage applied to the substrate 134. The ground rings 170 may be disposed to be spaced apart from each other and stacked vertically, and gas may be exhausted into a space between the ground rings 170. A material of the ground ring 170 may be a conductive material and may be a metal or a metal alloy.

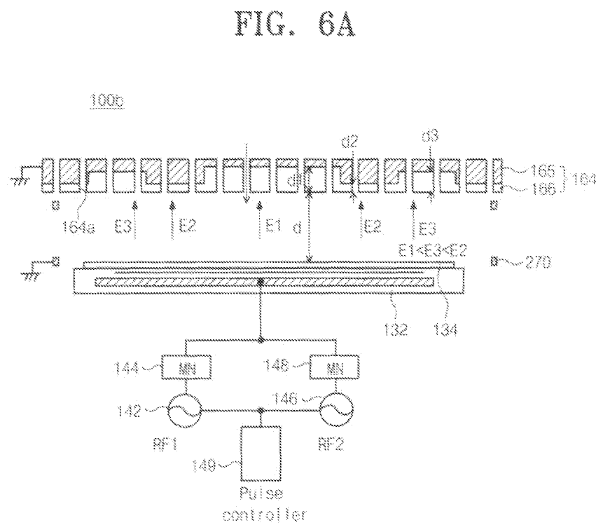

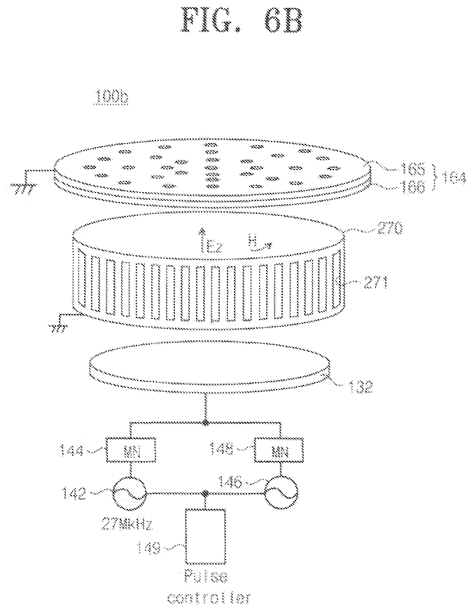

FIGS. 6A and 6B are a conceptual diagram and a perspective view illustrating a substrate treatment apparatus according to another embodiment of the present disclosure.

Referring to FIGS. 6A and 6B, a plasma substrate processing apparatus 100b includes: a process chamber 122; an upper electrode 164 disposed in the process chamber 124; a substrate holder 132 disposed below the upper electrode 164 and disposed to oppose the upper electrode to support the substrate; RF power sources 142 and 146 applying RF power to the substrate holder; and a ground cavity 270.

The ground cavity 270 may be disposed below the upper electrode to surround plasma between the substrate holder and the upper electrode, and may have a cylindrical shape. The ground cavity may include a plurality of slits 271, and an inner diameter of the ground cavity may be larger than an outer diameter of the substrate holder.

The upper electrode 164 may include: an upper electrode conductive plate 165 having a lower surface having different heights depending on location; and a compensation plate 166 having a dielectric constant and having different thicknesses depending on location to compensate for the height difference depending on location. A lower surface of the compensation plate 166 may be a coplanar surface.

A driving angular frequency ω of the RF power with a reduced standing wave effect may be defined as follows: ω=0.1 c/a. When a radius a of the ground cavity 270 is 0.15 m, a corresponding driving frequency may be about 38 MHz. Therefore, it may be preferable that the RF power source 142 uses a frequency of about 38 MHz or lower. That is, using the ground cavity 270 may lead to an increase in resonant frequency. Therefore, a driving frequency of the RF power suppressing a standing wave effect may be increased.

The ground cavity 270 may include a plurality of slits 271 to discharge reaction byproducts within a discharge space to the outside. An electric field component Ez may be blocked at the ground cavity 270 such that the ground cavity 270 electrically operate as a cavity or a resonator. That is, an extension direction of the slit 271 may extend in a direction of a central axis. The ground cavity 270 may be grounded to increase a ground area and increase the DC bias voltage. In addition, the ground cavity 270 may locally limit the capacitively-coupled plasma to increase the plasma density.

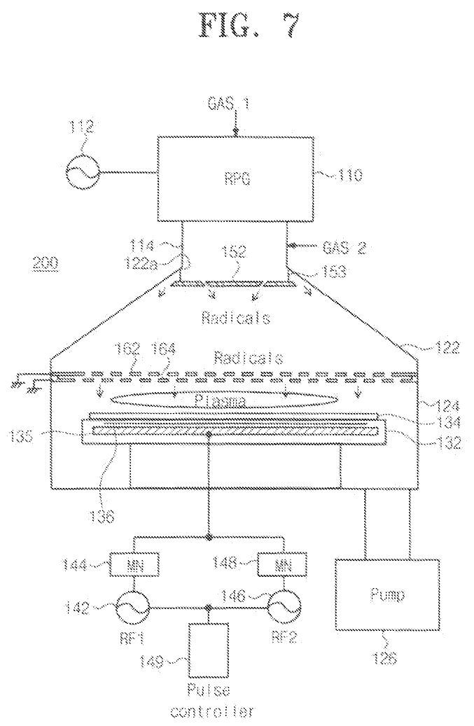

FIG. 7 is a conceptual diagram illustrating a substrate treatment apparatus according to another embodiment of the present disclosure.

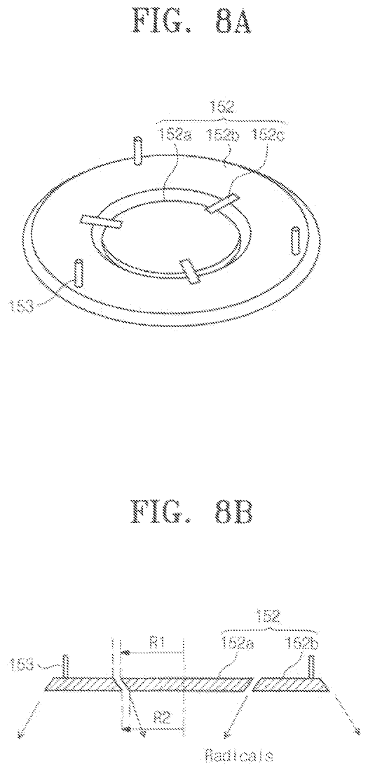

FIG. 8A is a perspective view illustrating a first baffle in the plasma substrate processing apparatus of FIG. 7.

FIG. 8B is a cross-sectional view of the first baffle of FIG. 8A.

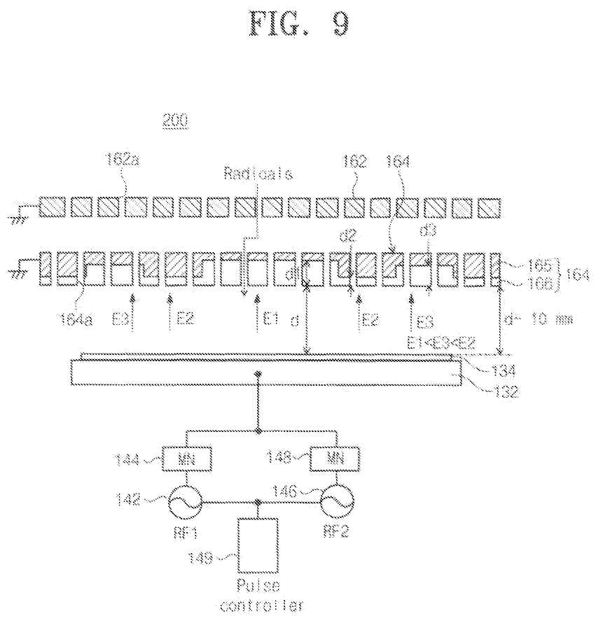

FIG. 9 is a conceptual diagram illustrating a second baffle and an upper electrode in the plasma substrate processing apparatus of FIG. 8.

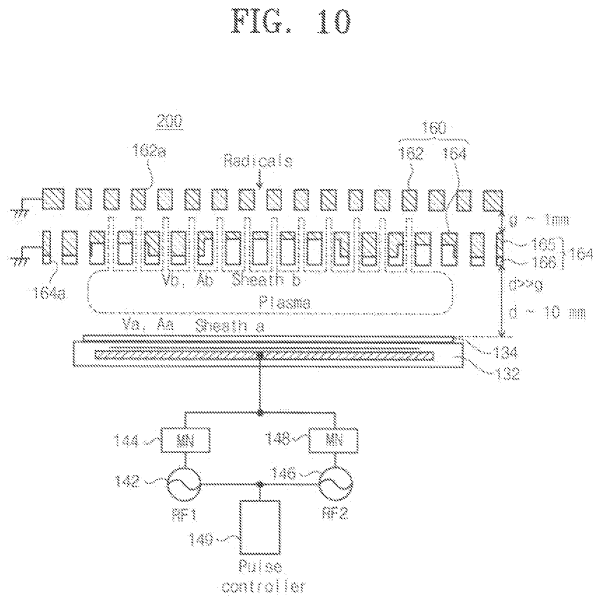

FIG. 10 is a conceptual diagram illustrating a second baffle and an upper electrode in the plasma substrate processing apparatus of FIG. 8.

Referring to FIGS. 7 to 10, the plasma substrate processing apparatus 200 may include: a process chamber 122; an upper electrode 164 disposed in the process chamber; a substrate holder 132 disposed below the upper electrode and disposed to oppose the upper electrode 164 to support the substrate; and RF power sources 142 and 146 applying RF power to the substrate holder.

The upper electrode 164 may include: an upper electrode conductive plate 165 having a lower surface having different heights depending on location; and a compensation plate 166 coupled to a lower portion of the upper electrode conductive plate to have different thicknesses depending on location to compensate for a height difference depending on location and having a dielectric constant. The lower surface of the compensation plate 166 is a coplanar surface.

The plasma substrate processing device 200 may further include: a remote plasma generator 110 generating remote plasma and active species; an auxiliary chamber 122 having an opening 120a connected to an output port 114 of the remote plasma generator 110 and receiving and diffusing the active species of the remote plasma generator 110 to be provided to the process chamber 124; a first baffle 152 disposed at the opening of the auxiliary chamber 122; and a second baffle 160 partitioning the auxiliary chamber 122 and the process chamber 124 and transmitting the active species.

The second baffle 162 may be disposed to be spaced apart from the upper electrode 164, may be electrically grounded, and may oppose the auxiliary chamber 124, and may include a plurality of first through-holes 162a. The upper electrode 166 may be electrically grounded and spaced apart from the second baffle 162, and may include a plurality of second through-holes 164a.

The remote plasma generator 110 may be an inductively-coupled plasma source including an induction coil (not illustrated) wound around a dielectric cylinder. The dielectric cylinder may be supplied with a first gas from the outside. A diameter of the dielectric cylinder may be 50 mm to 150 nm. The induction coil may be wound around the dielectric cylinder at least one turn, and may be supplied with RF power from a remote plasma RF power source 112. The frequency of the remote plasma RF power source 112 may be 400 kHz to 13.56 MHz. The induction coil may generate an inductively-coupled plasma inside the dielectric cylinder. Output power of the remote plasma RF power source may be several kW to several tens of kW. Accordingly, operating pressure of the remote plasma generator 110 may be several hundred mTorr to several tens of Torr. In the case of an etching process, the first gas may include a fluorine-containing gas. The remote plasma generator 110 may generate remote plasma and active species or neutral species decomposed from the first gas. The remote plasma generator 110 may control only characteristics of the plasma without considering the plasma spatial uniformity. An electron temperature may depend on pressure, and the plasma density may depend on the output power of the remote plasma RF power source. The remote plasma RF power source 112 may operate in continuous mode or pulse mode to control the characteristics of the remote plasma. Accordingly, the remote plasma generator 110 may independently control the density of active species and a density ratio of active species. For example, the remote plasma generator 110 may independently control the electron temperature using pressure and RF pulse mode. Accordingly, the density ratio of active species F, CF, CF₂, and CF₃ decomposed from CₓF_{y} gas may be controlled.

The active species may be provided to the auxiliary chamber 122. The remote plasma generator 110 may be connected to the auxiliary chamber 122 through the output port 114. A second gas may be additionally supplied to the output port 114. The second gas may be the same as or different from the first gas. The second gas may collide with the active species to reduce a temperature of the active species. The second gas may include at least one of oxygen-containing gas, hydrogen gas, and inert gas that are easy to generate plasma in the lower chamber.

The auxiliary chamber 122 may have a truncated cone shape. The opening 122a of the auxiliary chamber 122 may be disposed in a truncated portion. A lower portion of the auxiliary chamber 122 may have a cylindrical shape. The auxiliary chamber 122 may be formed of metal or a metal-alloy, and may be grounded.

The first baffle 152 may include: a disk 152a having an inclined outer surface; and a ring plate 152b having an inclined inner surface and an inclined outer surface and disposed to surround the disk 152a at a predetermined distance from the disk 152a. The outer surface of the disk 152a may have an outer diameter increasing with height. The inner surface of the ring plate 152b may have an inner diameter increasing with height. The disk 152a and the ring plate 152b may be fixed by a plurality of bridges 152c. The ring plate 152b may be fixed to the upper chamber 122 by a plurality of columns 153.

A space between the disk 152a and the ring plate 152b may form a concentric slit. Active species, permeating through the concentric slit, may be injected and diffused in a direction of a center of the auxiliary chamber 122. An outer surface of the ring plate 152b may have an outer diameter decreasing with height. Active species, permeating through a space between the outer surface of the ring plate and the upper chamber, may be injected and diffused in a direction of a wall of the auxiliary chamber 122. Accordingly, the active species may be widely diffused within the upper chamber 122 to form a uniform density distribution. The first baffle 152 may spatially distribute the active species for rapid diffusion. Accordingly, a height of the auxiliary chamber 122 may be reduced.

The first baffle 152 may be formed of a conductive material or an insulating material. The first baffle 152 may serve as a plasma blocking filter blocking plasma, generated from the remote plasma generator 110, and allowing active species to permeate therethrough. In addition, the first baffle 152 may serve to spatially distribute the active species. Vertically incident ions may collide with the inclined surface of the first baffle 152 while passing through the concentric slit of the first baffle 152. A maximum diameter R1 on the inclined outer surface of the disk 152a may be larger than a minimum diameter R2 on the inclined inner surface of the ring plate 152b.

According to a modified embodiment of the present disclosure, the ring plate 152b may be provided in plural. Accordingly, a concentric slit between the ring plates 152b may block the plasma through the inclined surface and inject active species in a specific direction. Accordingly, the first baffle 152 may provide sufficient conductance by a plurality of concentric slits. A height of the auxiliary chamber 122 may be decreased.

The process chamber 124 may receive the active species diffused from the auxiliary chamber 122. The inside of the process chamber 124 may have a cylindrical shape, and the process chamber 124 may be formed of metal or a metal-alloy. The process chamber 124 may be continuously connected to the auxiliary chamber 122. A vacuum pump 126 may be connected to the process chamber 124 to exhaust the process chamber 124. In addition, a pressure of the process chamber 124 may be several tens of m Torr to several hundreds of m Torr. Also, the pressure of the auxiliary chamber 122 may be higher than a pressure of the process chamber.

The second baffle 162 may partition the auxiliary chamber 122 and the process chamber 124 and transmit the active species. The second baffle 162 may be disposed to be spaced apart parallel to the upper electrode 164. The second baffle 162 may be electrically grounded, may oppose the auxiliary chamber 122, and may include a plurality of first through-holes 162a. The upper electrode 164 may be electrically grounded, may be spaced apart from the second baffle, and may include a plurality of second through-holes 164a. The first through-holes 162a and the second through-holes 164a may be disposed to avoid overlap each other.

The second baffle 162 may have a constant thickness, may be electrically grounded, may oppose the auxiliary chamber, and may include a plurality of first through-holes 162a. The second baffle 162 may be disposed in the cylindrical portion of the auxiliary chamber 122 to partition the auxiliary chamber 122 and the process chamber 124. The second baffle 162 may provide the active species of the auxiliary chamber 122 to the process chamber 124. The second baffle 162 may neutralize the capacitively-coupled plasma of the process chamber 124 to prevent the capacitively-coupled plasma from transmitting the auxiliary chamber 122, and may increase a contact area with the capacitively-coupled plasma.

The thickness of the second baffle 162 may be smaller than the thickness of the upper electrode 164. Accordingly, the second baffle 162 may provide a sufficiently large conductance with the first through-holes 162a and the small thickness. The upper electrode 164 may increase a contact area with plasma due to the large thickness.

A diameter of the second through-hole 164a may be more than twice a thickness of a plasma sheath between the upper electrode 164 and the plasma. Specifically, the diameter of the second through-hole 164a may be 5 millimeters to 10 millimeters. Accordingly, the plasma may permeate into the second through-hole 164a. The second through-hole 164a of the upper electrode 164 may increase a contact area with the plasma. The plasma, permeating into the second through-hole 164a, may collide with the second baffle 162 to be neutralized. The second baffle 162 may further increase the contact area with the plasma.

A gap between the second baffle 162 and the upper electrode 164 may be less than several millimeters. Specifically, the gap g between the second baffle 162 and the upper electrode 164 may be at a level of 1 millimeter to 5 millimeters. The gap g between the second baffle and the upper electrode is small enough to prevent plasma, reaching the second baffle 162 through the second through-hole 164a, from diffusing in a lateral direction.

A gap d between the substrate holder 132 and the lower surface of the upper electrode 164 (or a height of the discharge region) may be larger than the gap g between the second baffle and the upper electrode. The gap g between the substrate holder and the lower surface of the upper baffle may form a discharge space and may be 10 millimeters to 30 millimeters.

The upper electrode 164 may include: an upper electrode conductive plate 165 having a lower surface having different heights depending on location; and a compensation plate 166 having a dielectric constant and having different thicknesses depending on location to compensate for a height difference depending on location. A lower surface of the compensation plate 166 may be a coplanar surface.

A second through-hole 364a of the upper electrode 164 may be disposed to penetrate through the upper electrode conductive plate 165 and the compensation plate 166. The upper electrode 164 may have a constant thickness, and the thickness of the upper electrode conductive plate 165 may vary depending on location. The thickness of the compensation plate 166 may vary depending on location such that the thickness of the upper electrode 164 is maintained to be constant.

The compensation plate 166 may include at least one of silicon, silicon oxide, silicon nitride, or silicon oxynitride. The thickness of the compensation plate 166 may be largest in at least one of the central region and the edge region. The central region may be circular, and the edge region may be ring-shaped.

The RF power of the RF power sources 142 and 146 may generate a capacitively-coupled plasma between the substrate 134 and the upper electrode. A first plasma sheath a may be formed between the substrate and the plasma. In addition, a second plasma sheath b may be is formed between the upper electrode and the plasma. The first plasma sheath a and the second plasma sheath b may be capacitors circuitally. A first DC voltage Va may be applied to the first plasma sheath a, and a second DC voltage Vb may be applied to the second plasma sheath b. An area in which the plasma and the substrate 134 are in contact with each other is a first area Aa, and an area in which the plasma and the second baffle 160 are in contact with each other is a second area Ab.

The energy of the ions incident on the substrate 134 may depend on the first DC voltage Va. Accordingly, the second area Ab in which the second baffle 160 and the plasma are in contact with each other may be increased to increase the first DC voltage Va. For example, the upper electrode 164 may have a second through-hole 164a, large enough for the plasma to permeate therethrough, to increase the second area Ab.

FIG. 11 is a plan view illustrating a second baffle according to an embodiment of the present disclosure.

Referring to FIG. 11, the second baffle 162 may be electrically grounded, may oppose the auxiliary chamber, and may include a plurality of first through-holes 162a. The upper electrode 164 may be electrically grounded, may be spaced apart from the second baffle, and may include a plurality of second through-holes. The second through-hole 164a may be disposed to avoid overlapping the first through-hole 162a. A diameter of the first through-hole 162a may be smaller than a diameter of the second through-hole 164a. A thickness of the compensation plate 166 in the central region 164b and/or the edge region 164c may be greater than in other regions.

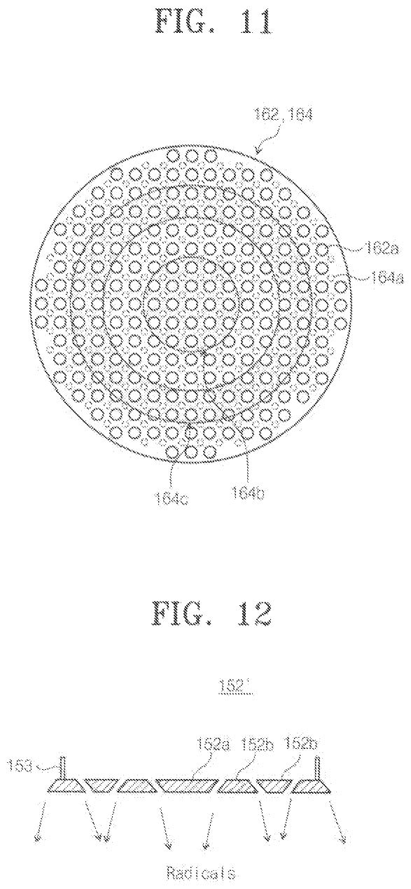

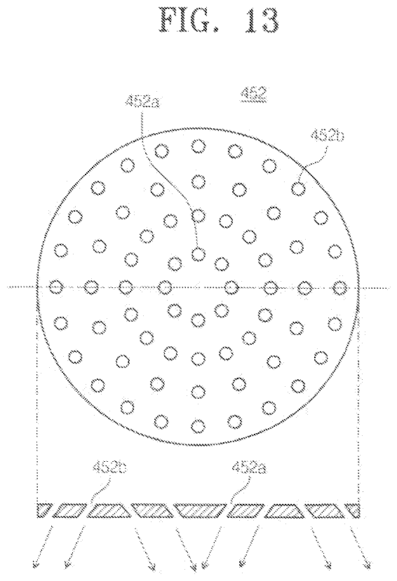

FIG. 12 is a cross-sectional view illustrating a first baffle according to another embodiment of the present disclosure.

Referring to FIG. 12, a first baffle 152′ may include a disk 152a having an inclined outer surface; and a plurality of ring plates 152b having an inclined inner surface and an inclined outer surface and disposed to surround the disk 152a at a predetermined interval.

A space between the disk 152a and the ring plate 152b and a space between the ring plates 152b may form a concentric slit. Active species, passing through the concentric slit between the disk 152a and the ring plate 152b, may diffuse toward a center of the auxiliary chamber 122.

The active species, passing through the concentric slits between the ring plates 152b, may diffuse toward a wall of the auxiliary chamber 122. The first baffle 152′ may spatially distribute the active species for rapid diffusion. Accordingly, a height of the auxiliary chamber 122 may be reduced.

FIG. 13 is a cross-sectional view illustrating a first baffle according to another embodiment of the present disclosure.

Referring to FIG. 13, the first baffle 452 may include a plurality of through-holes 452a and 452b in an oblique direction. The through-holes 452a in a central region may be inclined to inject active species in a direction of a central axis. The through-holes 452b in an edge region may be inclined to inject active species toward a wall of an auxiliary chamber. The first baffle 452 may spatially distribute the active species to achieve rapid diffusion. Accordingly, a height of the auxiliary chamber may be reduced.

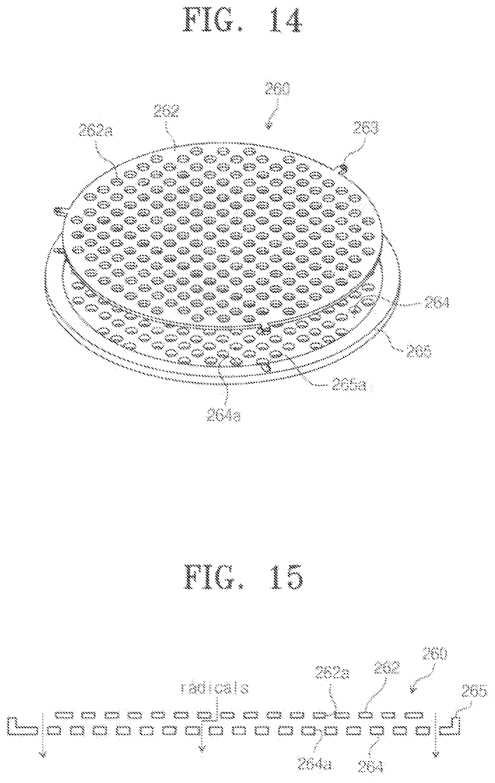

FIG. 14 is a perspective view illustrating an upper electrode and a second baffle according to an embodiment of the present disclosure.

FIG. 15 is a cross-sectional view of the upper electrode and the second baffle of FIG. 14.

Referring to FIGS. 14 and 15, a diameter of the second baffle 262 may be smaller than a diameter of the upper electrode 264. The diameter of the first baffle 152 is about 100 to 150 mm, and the diameter of the second baffle 262 is about 400 mm. The second baffle 262 may have a structure allowing active species to uniformly diffuse at a minimum distance from the substrate. Due to a difference in diameter between the first baffle 152 and the second baffle 262, the density of active species in a center portion of the second baffle 262 may be higher than at an edge thereof. The diameter of the second baffle 262 may be larger than the diameter of the upper electrode 264 to prevent a non-uniform spatial distribution of active species density in the auxiliary chamber 122 from being transferred to the process chamber 124. Accordingly, a larger number of active species may flow to an outer portion of the upper electrode 264. As a result, a uniform spatial distribution of active species density may be obtained in the process chamber 124.

The upper electrode 264 may have a ring-shaped projection 265 protruding at an outermost portion, and the ring-shaped projection 265 may include a protrusion 265a protruding for alignment with the upper baffle 262. The second baffle 262 may have a smaller diameter than the upper electrode 264, but may include a plurality of bridges 263 extending in a radial direction. The bridges 263 may be coupled and fixed to the projection 265a.

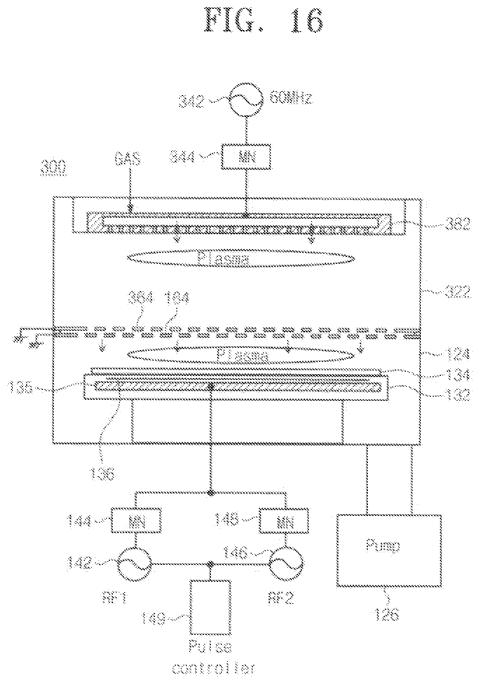

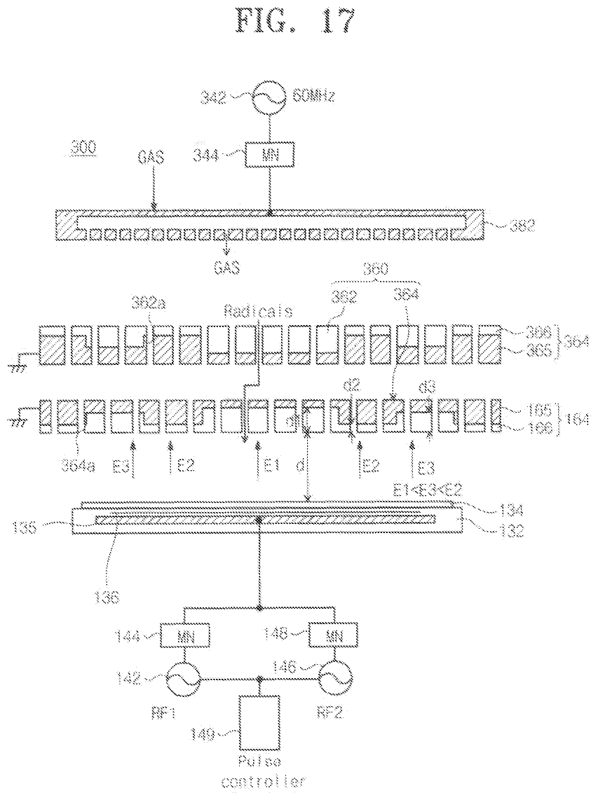

FIG. 16 is a conceptual diagram illustrating a substrate treatment apparatus according to another embodiment of the present disclosure.

FIG. 17 is a conceptual diagram illustrating an upper electrode and an auxiliary electrode of the substrate treatment apparatus of FIG. 16.

Referring to FIGS. 16 and 17, a substrate processing apparatus 300 may have a dual-chamber structure in which capacitively-coupled plasma is generated in an auxiliary chamber 322 and a process chamber 122, respectively. Active species generated in the auxiliary chamber may be provided to the process chamber 122 through an auxiliary ground electrode 364 and an upper electrode 164.

A substrate processing apparatus 300 may include: a process chamber 122; an upper electrode 164 disposed in the process chamber; a substrate holder 132 disposed below the upper electrode and disposed to oppose the upper electrode 164 to support the substrate; and RF power sources 142 and 144 applying RF power to the substrate holder. The upper electrode 164 may include: an upper electrode conductive plate 165 having a lower surface having a height varying depending on location; and a compensation plate 166 having a dielectric constant and a thickness varying depending on location to compensate for a height difference depending on location. The lower surface of the compensation plate is a coplanar plane.

An auxiliary plasma apparatus may include: an auxiliary chamber 322 connected to the process chamber; a power electrode 382 receiving RF power from the auxiliary RF power source 342 to generate capacitively-coupled plasma and active species in the auxiliary chamber 322; and an auxiliary ground electrode 364 partitioning the auxiliary chamber 322 and the process chamber 122 and transmitting the active species. The auxiliary ground electrode 364 may be disposed to be spaced apart from the upper electrode 164, may be electrically grounded, may oppose the auxiliary chamber 322, and may include a plurality of first through-holes 364a. The upper electrode 164 may be electrically grounded, may be disposed to be spaced apart from the auxiliary ground electrode, and may include a plurality of second through-holes 164a.

The auxiliary electrode 364 may include: an auxiliary electrode conductive plate 365 having an upper surface having a height varying depending on location; and a compensation plate 366 having a dielectric constant and a thickness varying depending on location to compensate for a height difference depending on location. An upper surface of the compensation plate 366 may be a coplanar surface. The auxiliary electrode 364 may have the same structure as the upper electrode. Accordingly, a standing wave effect, an edge effect, and a harmonic effect caused by a high-frequency RF of the auxiliary RF power source 342 may be compensated for by the auxiliary electrode 364 to have a spatially uniform plasma density distribution.

The auxiliary RF power source 342 may supply high-frequency RF power to a power electrode 382 through an impedance matching network 344. The power electrode 382 may include a gas buffer space and a plurality of holes, connected to the gas buffer space, to perform functions of a gas distributor supplying and distributing gas from the outside.

A frequency of the auxiliary RF power source 342 may be 40 MHz to 100 MHz. A standing wave effect is increased by a high frequency, but the compensation plate 366 of the auxiliary ground electrode may compensate for spatial non-uniformity of an electric field to generate uniform plasma and active species. The frequency and power of the auxiliary RF power source 342 may be optimized for the density and ratio of the active species.

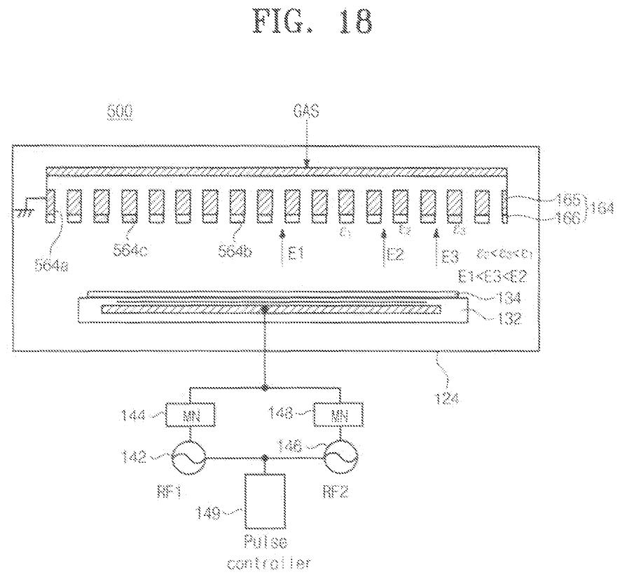

FIG. 18 is a conceptual diagram illustrating a substrate treatment apparatus according to another embodiment of the present disclosure.

Referring to FIG. 18, the plasma substrate processing apparatus 500 may include: a process chamber 124; an upper electrode 564 disposed in the process chamber; a substrate holder 132 disposed below the upper electrode and disposed to oppose the upper electrode 564 to support the substrate; and RF power sources 142 and 146 applying RF power to the substrate holder. The upper electrode 564 may include: an upper electrode conductive plate 565; and a compensation plate 566 coupled to a lower portion of the conductive plate and having a dielectric constant varying depending on location. A lower surface of the compensation plate may be a coplanar surface, and the compensation plate 566 may be coupled to an upper electrode conductive plate 565.

The upper electrode 564 may include a gas buffer space, receiving and distributing gas from the outside, and a plurality of through-holes connected to the gas buffer space to inject gas in a direction of the substrate holder.

The compensation plate 565 may have a constant thickness, but may have different dielectric constants ε1, ε2, and ε3 in a central region 564b and/or an edge region 564c. That is, electric field strength in the discharge region may depend on the dielectric constant of the compensation plate. Accordingly, a compensation plate having a different dielectric constant depending on location may provide different electric field strengths E1, E2, and E3 in a corresponding discharge region. That is, when the dielectric constant is large, the electric field strength in the corresponding discharge region may decrease. That is, a high-dielectric constant material may be used to reduce an electric field in the discharge region corresponding to a central region. A low-dielectric constant material may be used to reduce the electric field in the discharge region corresponding to a region surrounding the central region. For example, low-dielectric constant materials may include silicon oxide, silicon nitride, silicon oxynitride, aluminum oxide, and silicon. A high-dielectric constant materials may include aluminum nitride, Y₂O₃, ZrO₂, HfO₂, LaO₃, and BaO. The compensation plate may be an insulator or semiconductor having a dielectric constant, the upper electrode conductive plate may have a constant thickness, and the compensation plate may be divided into a plurality of components to have a dielectric constant varying depending on location.

Although the present disclosure and its advantages have been described in detail, it should be understood that various changes, substitutions and alterations can be made herein without departing from the spirit and scope of the disclosure as defined by the following claims.

1. A plasma substrate processing apparatus comprising:
a process chamber;
an upper electrode disposed in the process chamber;
a substrate holder disposed below the upper electrode and disposed to oppose the upper electrode to support the substrate; and
an RF power source applying RF power to the substrate holder,
wherein
the upper electrode comprises:
an upper electrode conductive plate having a lower surface having different heights from the substrate holder depending on location; and
a compensation plate coupled to a lower portion of the upper electrode conductive plate to have different thicknesses depending on location to compensate for a height difference depending on location and having a dielectric constant, and
a lower surface of the compensation plate is a coplanar surface.

2. The plasma substrate processing apparatus as set forth in claim 1, wherein
the upper electrode comprises a plurality of through-holes penetrating through the upper electrode conductive plate and the compensation plate.

3. The plasma substrate processing apparatus as set forth in claim 1, wherein
the upper electrode is electrically grounded.

4. The plasma substrate processing apparatus as set forth in claim 1, wherein
the compensation plate is an insulator or semiconductor having a dielectric constant,
the upper electrode has a constant thickness,
the upper electrode conductive layer has a thickness varying depending on location, and
the compensation plate has a thickness varying depending on location such that the thickness of the upper electrode is maintained to be constant.

5. The plasma substrate processing apparatus as set forth in claim 1, wherein
the compensation plate comprises at least one of silicon, silicon oxide, silicon nitride, and silicon oxynitride.

6. The plasma substrate processing apparatus as set forth in claim 1, wherein
the thickness of the compensation plate is greatest in at least one of a central region and an edge region,
the central region has a circular shape, and
the edge region has a ring shape.

7. The plasma substrate processing apparatus as set forth in claim 1, further comprising:
at least one ground ring,
wherein
the ground ring is disposed below the upper electrode to surround plasma between the substrate holder and the upper electrode and has a ring shape, and
an inner diameter of the ground ring is larger than an outer diameter of the substrate holder.

8. The plasma substrate processing apparatus as set forth in claim 1, further comprising:
at least one ground cavity,
wherein
the ground cavity is disposed below the upper electrode to surround plasma between the substrate holder and the upper electrode and has a cylindrical shape,
the ground cavity comprises a plurality of slits, and
an inner diameter of the ground cavity is larger than an outer diameter of the substrate holder.

9. The plasma substrate processing apparatus as set forth in claim 1, further comprising:
a remote plasma generator generating remote plasma and active species;
an auxiliary chamber having an opening connected to an output port of the remote plasma generator and receiving and diffusing the active species of the remote plasma generator to be provided to the process chamber;
a first baffle disposed at the opening of the auxiliary chamber; and
a second baffle partitioning the auxiliary chamber and the process chamber and transmitting the active species,
wherein
the second baffle is disposed to be spaced apart from the upper electrode,
the second baffle is electrically grounded, opposes the auxiliary chamber, and comprises a plurality of first through-holes, and
the upper electrode is electrically grounded, is spaced apart from the second baffle, and comprises a plurality of second through-holes.

10. The plasma substrate processing apparatus as set forth in claim 9, wherein
the second through-holes are disposed to avoid overlapping the first through-holes.

11. The plasma substrate processing apparatus as set forth in claim 1, wherein
a diameter of the second through-hole is more than twice a thickness of the plasma sheath between the upper electrode and plasma, and
the plasma permeates into the second through-holes.

12. The plasma substrate processing apparatus as set forth in claim 9, wherein
a gap between the second baffle and the upper electrode is less than several millimeters, and
a gap between the substrate holder and the lower surface of the upper electrode is larger than the gap between the second baffle and the upper substrate.

13. The plasma substrate processing apparatus as set forth in claim 9, wherein
a diameter of the first through-hole of the second baffle is smaller than a diameter of the second through-hole of the upper electrode.

14. The plasma substrate processing apparatus as set forth in claim 9, wherein
the second through-holes are disposed to avoid overlapping the first through-holes.

15. The plasma substrate processing apparatus as set forth in claim 1, wherein
the first baffle comprises:
a disk having an inclined outer surface; and
a ring plate having an inclined inner surface and an inclined outer surface and disposed to surround the disk with a predetermined gap from the disk,
the outer surface of the disk has an outer diameter increasing with height, and
the inner surface of the ring plate has an inner diameter increasing with height.

16. The plasma substrate processing apparatus as set forth in claim 5, wherein
the disk and the ring plate are fixed by a plurality of bridges, and
the ring plate is fixed to the auxiliary chamber by a plurality of columns.

17. The plasma substrate processing apparatus as set forth in claim 9, wherein
the first baffle comprises a plurality of through-holes,
through-holes disposed at a center of the first baffle are inclined holes directed to a central axis, and
the through-holes disposed at an edge of the first baffle are inclined holes directed to the outside.

18. The plasma substrate processing apparatus as set forth in claim 1, wherein
the RF power source comprises a low-frequency power source and a high-frequency power source,
the plasma substrate processing apparatus further comprises a pulse controller controlling the low-frequency RF power source and the high-frequency RF power source, and
each of the low-frequency RF power source and the high-frequency RF power source operates in pulse mode.

19. The plasma substrate processing apparatus as set forth in claim 9, wherein
the remote plasma generator is an inductively-coupled plasma source comprising an induction coil wound around a dielectric cylinder.

20. The plasma substrate processing apparatus as set forth in claim 19, wherein
a diameter of the output port of the remote plasma generator is 50 millimeters to 150 millimeters,
the auxiliary chamber has a truncated cone shape, and
the opening of the auxiliary chamber is disposed in a truncated portion.

21. The plasma substrate processing apparatus as set forth in claim 1, further comprising:
an auxiliary chamber connected to the process chamber;
a power electrode receiving RF power from an auxiliary RF power source to generate capacitively-coupled plasma and active species in the auxiliary chamber; and
an auxiliary ground electrode partitioning the auxiliary chamber and the process chamber and transmitting the active species,
wherein
the auxiliary ground electrode is disposed to be spaced apart from the upper electrode,
the auxiliary ground electrode is electrically grounded, opposes the auxiliary chamber, and comprises a plurality of first through-holes, and
the upper electrode is electrically grounded, is spaced apart from the auxiliary ground electrode, and comprises a plurality of second through-holes.

22. The plasma substrate processing apparatus as set forth in claim 21, wherein
the auxiliary ground electrode comprises:
an auxiliary electrode conductive plate having an upper surface having a height varying on location; and
a compensation plate coupled to an upper portion of the auxiliary electrode conductive plate to have a thickness varying depending on location to compensate for a height difference depending on location and have a dielectric constant, and
the upper surface of the compensation plate is a coplanar surface.

23. A plasma substrate processing apparatus comprising:
a process chamber;
an upper electrode disposed in the process chamber;
a substrate holder disposed below the upper electrode and disposed to oppose the upper electrode to support the substrate; and
an RF power source applying RF power to the substrate holder,
wherein
the upper electrode comprises:
an upper electrode conductive plate; and
a compensation plate coupled to a lower portion of the conductive plate and having a dielectric constant varying depending on location,
a lower surface of the compensation plate is a coplanar surface, and
the compensation plate is coupled to the upper electrode conductive plate.

24. The plasma substrate processing apparatus as set forth in claim 23, wherein
the compensation plate is an insulator or semiconductor having a dielectric constant,
the upper electrode conductive plate has a constant thickness, and
the compensation plate is divided into a plurality of components to have a different dielectric constant varying depending location.

25. The plasma substrate processing apparatus as set forth in claim 23, wherein
the upper electrode is grounded.

26. A plasma substrate processing apparatus comprising:
a process chamber;
an upper electrode disposed in the process chamber;
a substrate holder disposed below the upper electrode and disposed to oppose the upper electrode to support the substrate;
an RF power source applying RF power to the substrate holder; and
at least one ground cavity,
wherein
the ground cavity is disposed below the upper electrode to surround plasma between the substrate holder and the upper electrode and has a cylindrical shape,
the ground cavity comprises a plurality of slits, and
an inner diameter of the ground cavity is larger than an outer diameter of the substrate holder.
